(19) United States
(12) Patent Application Publication
(10) Pub. No.: US 2003/0042133 A1
(43) Pub. Date: Mar. 6, 2003

(54) Method for depositing a metal barrier layer

(76) Inventors: Jae-Wook Lee, Suwon-Si (KR); Yoon-Bon Koo, Suwon-Si (KR)

Correspondence Address: VOLENTINE FRANCOS, P.L.L.C., 12200 Sunrise Valley Drive, Suite 150, Reston, VA, 20191, US

(21) Appl. No.: 10/229,174

(22) Filed: Aug. 28, 2002

(30) Foreign Application Priority Data
Aug. 28, 2001 (KR) 2001-51931

(51) Int. Cl. C23C 14/32; H01L 21/44; C23C 14/00

(52) U.S. Cl. 204/192.17; 204/192.15; 438/656; 438/685

(57) ABSTRACT

A substrate is placed in a sputter chamber so as to be spaced from a target contained in the chamber. A gaseous impurity is provided into the sputter chamber so as to control a pressure within the chamber in a pressure transition range. A first pressure in the chamber when during an increase in pressure is different from a second pressure in the chamber during a decrease in pressure, while an equal amount of the nitrogen gas is provided into the sputter chamber. Accelerated particles collide with the target to sputter the metal material from the target. Accordingly, a metal barrier layer containing an impurity comprised of the gaseous impurity and the metal material is deposited on the substrate.

### BACKGROUND OF THE INVENTION

1. Field of the Invention

The present invention relates to a method for depositing a metal barrier layer, and more particularly, the present invention relates to a method for uniformly depositing a titanium and/or titanium nitride barrier layer via sputtering.

2. Description of the Related Art

Currently, due to the widespread usage of computers in information media, semiconductor memory devices are being developed at a rapid pace to provide higher memory storage capacities and fasters operating speeds. To this end, current technologies focus on the realization of memory devices having an increased degree of integration, response speed, and reliability. Much attention has particularly been given to technologies which improve operational and process characteristics of metal wiring layers within memory devices.

Metal wiring layers have typically been made of aluminum or aluminum alloys. Aluminum, however, can exhibit junction spiking which results from the dissolution of silicon into the aluminum and aluminum into the silicon. In an effort to avoid junction spiking, the metal wiring layers have been formed by using an Al-1%Si material that is over-saturated with silicon. Silicon is extracted from the metal wiring layer containing the Al-1%Si material when the metal wiring layer is reflowed at a temperature of no less than about 450C.° Thus, the extracted silicon forms Si residues and Si nodules, which disadvantageously increase an electrical resistance of the metal wiring layer.

As such, more recent technologies adopt a metal barrier layer between the silicon substrate and the metal wiring layer and/or between the metal wiring layer and an insulation layer. The metal barrier layer acts as an anti-diffusion layer for preventing material dissolution at the layer interfaces, thus preventing the generation of the junction spiking, and the formation of Si residue and Si nodules.

In addition, metal wiring layers have been formed having multi-layer structures so as to improve the degree of integration the semiconductor devices. To reduce an electromigration between a lower layer and an upper layer and to reduce thermal stress during subsequent processes, the metal barrier layer has been formed as a buffer layer between upper and lower metal wiring layers.

Examples of metal barrier layers are disclosed in U.S. Pat. No. 5,904,561 (issued to Tseng), U.S. Pat. No. 5,970,374 (issued to Teo), U.S. Pat. No. 5,998,870 (issued to Lee et al.) and U.S. Pat. No. 6,033,983 (issued to Lee et al.).

Typically the metal barrier layer is constituted as a titanium layer and/or a titanium nitride layer which is usually formed by a sputtering. U.S. Pat. No. U.S. Pat. No. 5,958,193 (issued to Brugge) and U.S. Pat. No. 6,096,176 (issued to Van Buskirk) describe examples of the sputter depositing of titanium and/or titanium nitride barrier layers.

When the metal barrier layer is deposited by sputtering on a structure having an opening defined by elevated and recessed regions, it is difficult to deposit the metal barrier layer at a uniform thickness. This is because the distance between the substrate having the structure formed thereon and a target disposed in a sputter chamber is quite small, such as about 50 mm. As such, the step coverage of the metal barrier layer as deposited in the opening is not favorable. Furthermore, when the metal barrier layer is deposited at an opening having an aspect ratio of 2 or more, the step coverage is seriously deficient.

Recently, a sputter chamber having an increased distance of about 170 mm between the substrate and the target has been employed to enhance the step coverage of the deposited metal barrier layer. It has been found that such a sputter chamber may be favorably employed to deposit a titanium barrier layer. On the other hand, a titanium nitride barrier layer is not so easily deposited on the substrate because nitrogen gas is generally non-uniformly supplied into the sputter chamber. For this reason, the deposition of the titanium nitride barrier layer is accomplished by providing a large amount of the nitrogen gas into the chamber. The use of such a large amount of nitrogen gas disadvantageously results in frequent maintenance of the sputter chamber. In addition, the deposited titanium nitride layer exhibits a higher resistance at the substrate portion containing the opening.

As such, it has proven difficult using conventional techniques to deposit a metal barrier layer, such as titanium and titanium nitride layers, having good step coverage and low resistance.

### SUMMARY OF THE INVENTION

An objective of the present invention is to provide a method for depositing a metal barrier layer having a good step coverage and low resistance.

Another objective of the present invention is to provide a method for depositing a titanium nitride barrier layer having a good step coverage and low resistance.

According to one aspect of the invention, a substrate is placed in a sputter chamber such that the substrate and a metal target are separated by a given distance within the sputter chamber. A gaseous impurity is introduced into the sputter chamber to control a pressure of the sputter chamber within a transition range. The transition range exhibits a first pressure value when raising the pressure in the sputter chamber and a second pressure value when lowering the pressure in the sputter chamber after raising the pressure. The first pressure value is different from the second pressure value at an equal amount of the gaseous impurity is being introduced into the sputter chamber. Accelerated particles collide with the target to sputter the metal material from the target, thereby depositing a metal barrier layer containing an impurity comprised of the gaseous impurity and the metal material on the substrate.

According to a second aspect of the present invention, a substrate is placed in a sputter chamber such that the substrate and a titanium metal target are separated by a given distance within the sputter chamber. Accelerated particles collide with the target to sputter the titanium metal from the target, thereby depositing a titanium metal layer on the substrate. Then, nitrogen gas is introduced into the sputter chamber to control a pressure of the sputter chamber in a transition range. The transition range has a first pressure value when raising the pressure in the sputter chamber and a second pressure value when lowering the pressure in the sputter chamber after raising the pressure. The first pressure value is different from the second pressure value at an equal amount of the nitrogen gas is being introduced into the sputter chamber. Then, the accelerated particles collide with the target to sputter the titanium material from the target, thereby depositing a titanium nitride layer containing the titanium material and nitrogen comprised of the nitrogen gas on the titanium layer.

The methods of the invention allow for the deposition of a metal barrier layer having a good step coverage and a low resistance. In addition, the methods provide for the deposition of a titanium nitride layer having a good step coverage and a lower resistance on a titanium layer.

### BRIEF DESCRIPTION OF THE DRAWINGS

The features and advantages of the present invention will become more readily apparent from the detailed description that follows, with reference to the accompanying drawings, in which:

FIG. 1 is a schematic view showing a sputtering apparatus for depositing a metal barrier layer according to an embodiment of present invention;

FIG. 2 is a graph showing a pressure distribution according to an amount of nitrogen gas provided into the sputtering chamber of the sputtering apparatus as shown in FIG. 1;

FIGS. 3A to 3C are cross-sectional views for describing a method of depositing a metal barrier layer, including a titanium layer and a titanium nitride layer, according to an embodiment of present invention;

FIG. 4 is a graph illustrating an electrical resistance distribution of a metal barrier layer deposited according to an embodiment of present invention, and an electrical resistance distribution of metal barrier layers deposited according to a conventional method;

FIGS. 5A to 5G are cross-sectional views for describing a method of depositing a metal wiring layer including a metal barrier layer in accordance with an embodiment of the present invention; and

FIG. 6 is a schematic view showing an apparatus for performing the method as shown in FIGS. 5A to 5G.

### DETAILED DESCRIPTION OF THE PREFERRED EMBODIMENTS

In the deposition of a metal barrier layer according to the method of the present invention, a substrate is placed into a sputter chamber. The distance between the substrate and a target disposed in the sputter chamber is sufficient so as to uniformly deposit the metal material sputtered from a target onto the substrate. In the example herein, the metal material of the target is a titanium material.

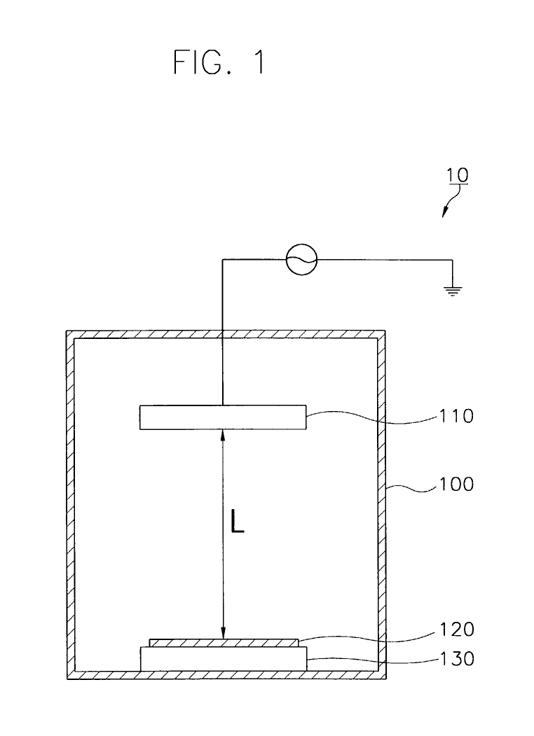

FIG. 1 shows a sputter apparatus 10 for depositing the metal barrier layer. Referring to FIG. 1, the apparatus 10 includes a sputter chamber 100, a target 110 disposed at an upper portion in the sputter chamber 100, and a plate 130 disposed in opposition to the target 110. A substrate 120 is placed on the plate 130. To ensure uniform deposition, the distance (L) between the substrate 120 and the target 110 is at least 150 mm, preferably 170 mm. Also, the apparatus 10 may further include a member (not shown) for applying radio frequency power to the plate 130.

As mentioned above, since the distance (L) is at least 150 mm, the metal wiring layer is uniformly deposited on the substrate 120, particularly where the substrate 120 has elevated regions and recessed regions on its surface. For example, the elevated regions and recessed regions may be defined by a structure on the substrate which includes an opening that exposes the surface of the substrate. When a metal wiring layer is formed utilizing the sputter chamber 100, the metal wiring layer completely fills a bottom area and a sidewall area of the opening portion. In semiconductor devices having a multi-layer structure, the metal wiring layer can completely cover the bottom area and the sidewall area of the opening portion. Since the metal wiring layer has a good step coverage, the metal wiring layer can be advantageously applied to a structure having a multi-layer structure.

A gaseous impurity is provided in the sputter chamber 100 so as to establish a predetermined pressure in the sputter chamber 100. Here, the gaseous impurity has a transition range, and the predetermined pressure is controlled within the transition range in which the gaseous impurity is in an unstable state. In the transition range, a first pressure value in the sputter chamber 100 when increasing the pressure in the sputter chamber is different from a second pressure value in the sputter chamber 100 when decreasing the pressure in the sputter chamber while an equal amount of the gaseous impurity is being provided into the sputter chamber 100.

Particularly, the predetermined pressure is controlled by providing a first amount of the gaseous impurity into the sputter chamber 100 to obtain a higher pressure than the pressure in the transition range and then by providing a second amount of the gaseous impurity which is smaller than the first amount of gaseous impurity into the sputter chamber 100 to obtain a lower pressure in the sputter chamber 100. In practice, the pressure of the transition range is controlled after applying a higher pressure than that of approximately 4 Torr in the sputter chamber 100. The pressure in the transition range is approximately 2-4 Torr. Here, applying the higher pressure is controlled in about 2-4 seconds, and the pressure in the transition range is controlled in about 18-24 seconds. Furthermore, the pressure in the transition range is controlled at a room temperature of about 18-25C.°

The gaseous impurity is preferably nitrogen gas.

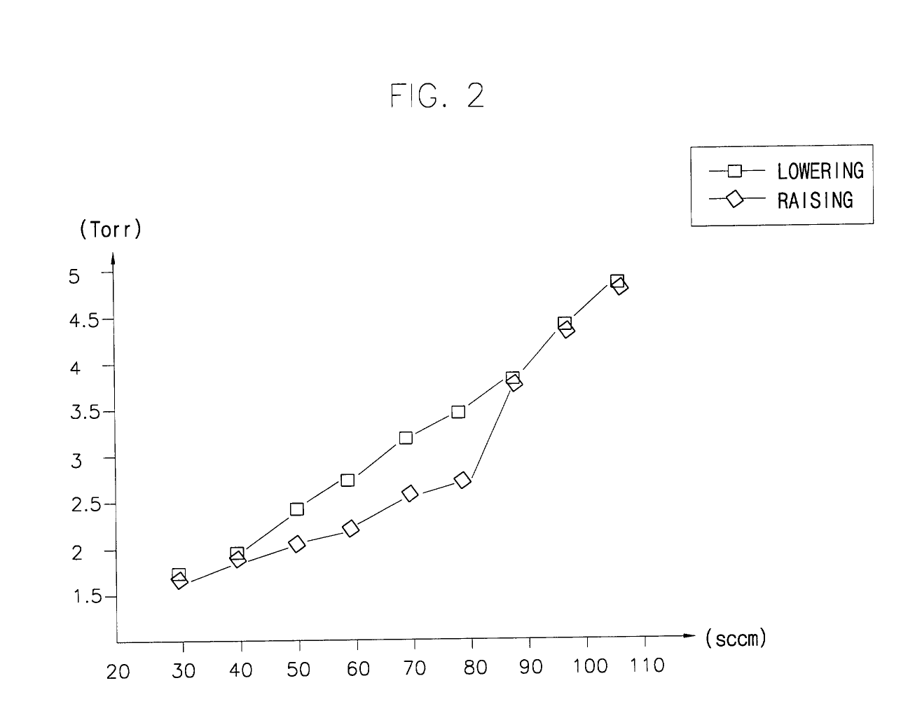

FIG. 2 is a graph showing the pressure distribution according to the amount of nitrogen gas provided into the sputter chamber of the sputtering apparatus as shown in FIG. 1.

Referring to FIG. 2, symbol ⋄ represents the pressure distribution in the case of raising the pressure in the sputter chamber. Symbol □ represents the pressure distribution in the case of lowering the pressure in the sputter chamber.

When the pressure is raised in the sputter chamber, a first pressure is about 1.5 Torr when introducing the nitrogen gas of about 30 sccm into the sputter chamber, a second pressure is about 2 Torr when introducing the nitrogen gas of about 50 sccm into the sputter chamber, a third pressure is about 2.5 Torr when introducing the nitrogen gas of about 70 sccm into the sputter chamber, a fourth pressure is about 4 Torr when introducing the nitrogen gas of about 90 sccm into the sputter chamber, and a fifth pressure is about 4.5 Torr when introducing the nitrogen gas of about 110 sccm into the sputter chamber. When the pressure is lowered in the sputter chamber, the sixth pressure is about 4 Torr when introducing the nitrogen gas of about 90 sccm into the sputter chamber, a seventh pressure is about 3.5 Torr when introducing the nitrogen gas of about 70 sccm into the sputter chamber, and an eighth pressure is about 2.5 Torr when introducing the nitrogen gas of about 50 sccm into the sputter chamber.

From the figure, it can be noted that the transition range generated by the nitrogen gas is about 2 Torr to about 4 Torr. That is, the pressure transition range is defined by the plurality of first pressure values ⋄ during a increase in the pressure within the sputter chamber and by a plurality of second pressure values □ during a decrease in the pressure within the sputter chamber which occurs after the increase in the pressure, wherein the first pressure values ⋄ are different than the second pressure values □ at each equal amount of the nitrogen being introduced into the sputter chamber.

Accelerated particles collide with the target and the metal material is released from the target. Thus, the metal barrier layer containing an impurity comprised of the gaseous impurity and the metal material is deposited on the substrate.

As mentioned above, when the metal material is titanium and the gaseous impurity is nitrogen gas, a titanium nitride layer is deposited as the metal barrier layer on the substrate.

Hereinafter, the method of depositing the metal barrier layer including the titanium nitride layer will be described in detail with reference to the accompanying drawings.

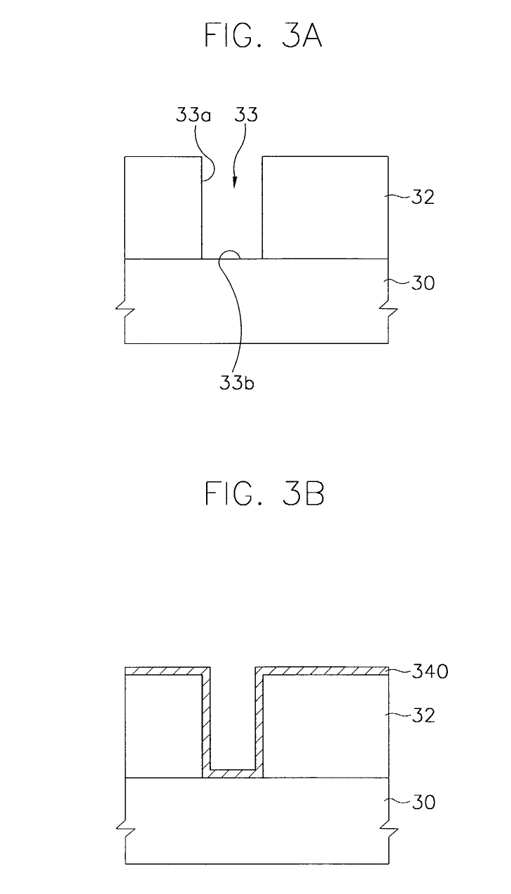

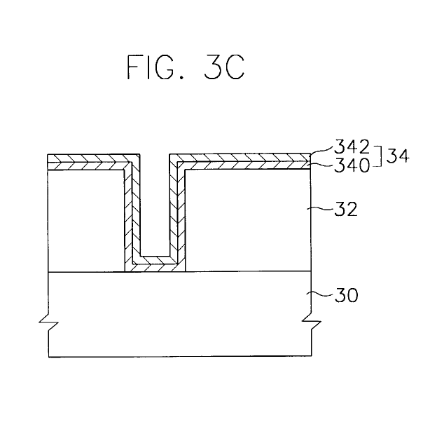

FIGS. 3A to 3C are sectional views showing a method for depositing a metal barrier layer including a titanium layer and a titanium nitride layer.

Referring to FIG. 3A, a substrate 30 is introduced in the sputter chamber of the sputtering apparatus. The substrate 30 has an insulation layer 32 formed thereon. The insulation layer 32 has an opening portion 33 partially exposing a surface of the substrate 30. In the sputter chamber, a target containing titanium material is installed. When the substrate 30 is placed into the sputter chamber, the space between the substrate 30 and the target is at least 150 mm, preferably about 170 mm, so that the titanium metal material is sufficiently deposited on the sidewall 33a and the bottom 33b of the opening portion 33.

Referring to FIG. 3B, a titanium layer 340 is deposited continuously on a sidewall 33a and a bottom 33b of the opening portion 33 and on a top surface of the insulation layer 32. Since the distance between the target and the substrate is sufficiently large, the titanium layer 340 is uniformly deposited on the sidewall 33a and the bottom 33b of the opening portion 33 and on the top surface of the insulation layer 32. As a result, the titanium layer 340 having a good step coverage can be deposited on the sidewall 33a and the bottom 33b of the opening portion 33 and on the top surface of the insulation layer 32.

Particularly, accelerated argon particles collide with the target to sputter the titanium material from the target. The sputtered titanium material is deposited on the sidewall 33a and the bottom 33b of the opening portion 33 and on the top surface of the insulation layer 32, so that the titanium layer 340 having a deposition thickness of about 250-350 Å, preferably, about 300 Å, is formed on the sidewall 33a and the bottom 33b of the opening portion 33 and on the top surface of the insulation layer 32.

Referring FIG. 3C, a titanium nitride layer 342 containing nitrogen and titanium material is deposited on the titanium layer 340. The titanium nitride layer 342 is also uniformly deposited on the titanium layer 340 formed on the sidewall 33a and the bottom 33b of the opening portion 33 since the distance between the target and the substrate is sufficiently large. As a result, the titanium nitride layer 342 having a good step coverage is deposited on the titanium layer 340.

Particularly, after forming the titanium layer 340 on the insulation layer 32 and the opening portion 33, the nitrogen gas is provided into the sputter chamber to control the pressure so that the transition range may be generated in the sputter chamber. At first, the pressure is controlled so have to have a higher pressure than the transition range, and then the pressure is controlled to be in the transition range.

For example, nitrogen gas of 100 sccm is introduced into the sputter chamber for three seconds so the pressure in the chamber is controlled to have a pressure of 4 Torr. Then, nitrogen gas of 55 sccm is introduced into the sputter chamber at the room temperature of 18 to 25C.° for 20 seconds. Accordingly, the pressure in the chamber is controlled at a pressure of 2.5 Torr. Here, the pressure is lowered after the pressure is initially raised because the transition range by generated the nitrogen gas is more stable in the case of lowering the pressure in the sputter chamber than in the case of raising the pressure in the sputter chamber. The accelerated argon particles are bombarded to the target to sputter the titanium material from the target, so that nitrogen atoms of the nitrogen gas and the sputtered titanium material are deposited on the titanium layer 340. Thus, a titanium nitride layer 342 is formed on the titanium layer 340 by means of the deposition of the nitrogen atoms and the titanium metal. At this time, the deposition thickness of the titanium nitride layer 342 is about 250 to 350 Å, preferably about 300 Å.

The metal barrier layer 34, comprising the titanium layer 340 and the titanium nitride layer 342 obtained in accordance with the method as above, has good step coverage. When the metal barrier layer 34 for a contact hole or a via hole is formed, the metal barrier layer has an electrical resistance of 0.55-0.80 ohm per each contact or via.

Electrical Resistance Distribution Measurement

A titanium nitride layer was deposited on a semiconductor substrate having a via or contact hole at a pressure of 2.5 Torr, 4 Torr and 4.5 Torr by using nitrogen gas. The titanium nitride layer had a thickness of about 300 Å and was formed on a titanium layer having a thickness of about 300 Å. After forming the titanium nitride layer, an electrical resistance was measured on each contact or via.

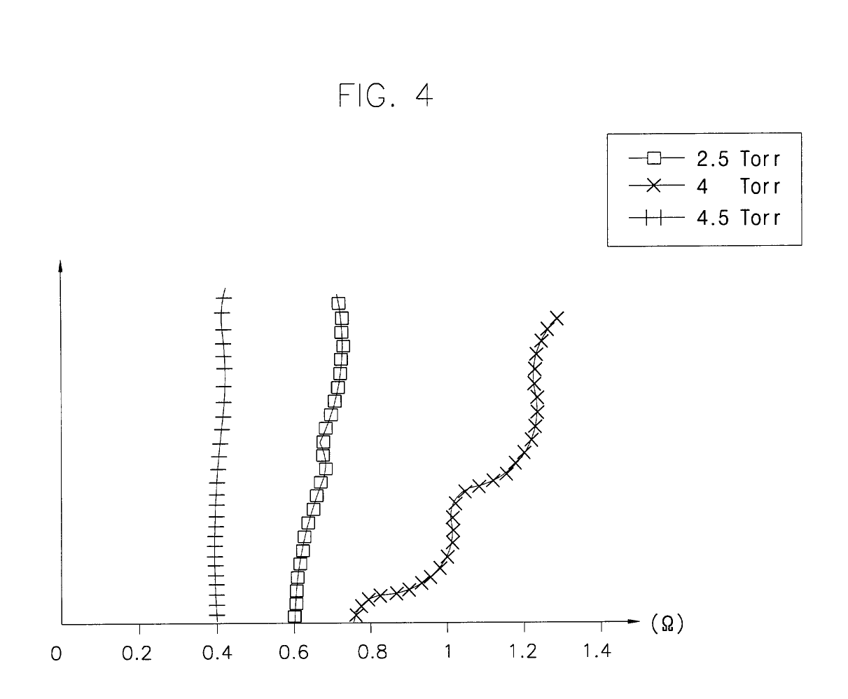

FIG. 4 shows electrical resistance distributions measured from the metal barrier layer obtained as above.

A symbol □ represents a curve illustrating the electrical resistance of the metal barrier layer including the titanium nitride layer formed under the pressure of about 2.5 Torr. The measured electrical resistance of the metal barrier layer was about 0.6-0.8 ohm per each contact or via.

A symbol × represents a curve illustrating the electrical resistance of the metal barrier layer including the titanium nitride layer formed at the pressure of 4.0 Torr. The measured electrical resistance of the metal barrier layer was about 0.8-1.2 ohm per each contact or via.

A symbol = represents a curve illustrating the electrical resistance of the metal barrier layer including the titanium nitride layer formed under the pressure of about 4.5 Torr. The measured electrical resistance of the metal barrier layer was about 0.4 ohm per each contact or via.

The electrical resistance of the metal barrier layer including the titanium nitride layer formed under a pressure of 4.5 Torr was best. However, the deposition process at the pressure of 4.5 Torr required a large amount of nitrogen gas (at least 115 sccm). The consumed nitrogen gas was great so that frequent maintenance routines are necessary, and thus the high pressure is considered not preferable in spite of the good electrical resistance. When the titanium nitride layer was deposited at a pressure of 4 Torr, the measured electrical resistance was high and the distribution thereof was not uniform. Thus, the pressure of 4 Torr is not preferable for forming the titanium nitride layer. Rather, it the preferable condition is when the titanium nitride layer is deposited at a pressure of 2.5 Torr, which is within the transition range.

Also, at a pressure lower than 2.0 Torr, the titanium nitride layer is not easily deposited on the titanium layer because the nitrogen gas was not sufficiently introduced into the sputter chamber (no more than 45 sccm). When the nitrogen gas was insufficient, a titanium layer was formed instead of the titanium nitride layer. Accordingly, the titanium nitride layer is deposited under the pressure of 2.5 Torr.

The metal barrier layer having a good step coverage and a lower electrical resistance may be easily deposited when the deposition process is implemented under the pressure in the transition range and in a sputter chamber having a sufficient distance between the target and the substrate.

Hereinafter, the method of forming the metal wiring layer having the multilayer structure that includes the metal barrier layer will be described in detail with reference to the accompanying drawings.

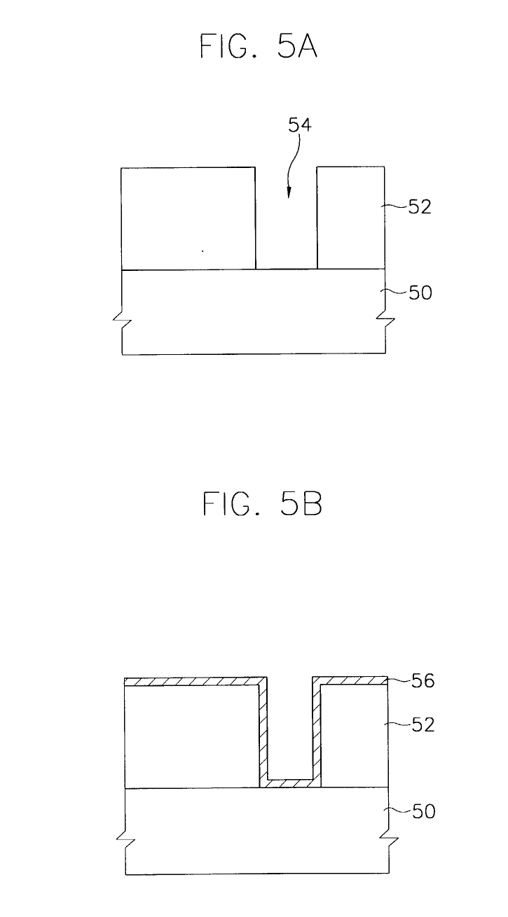

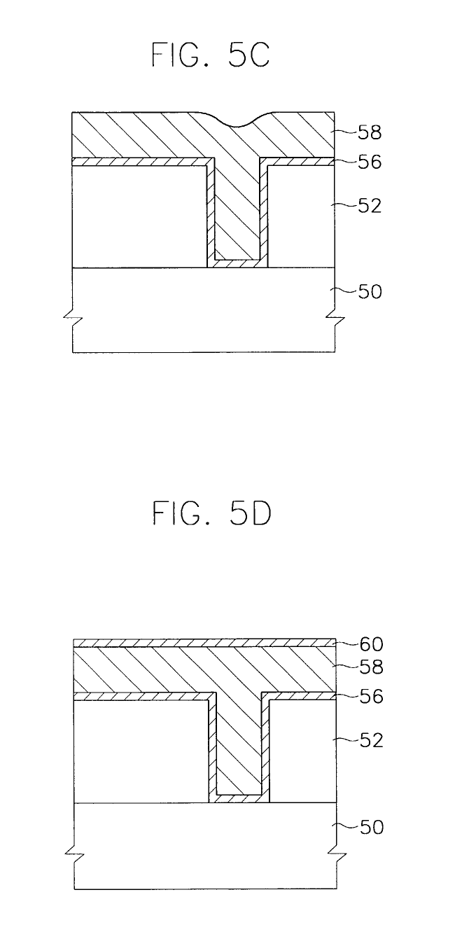

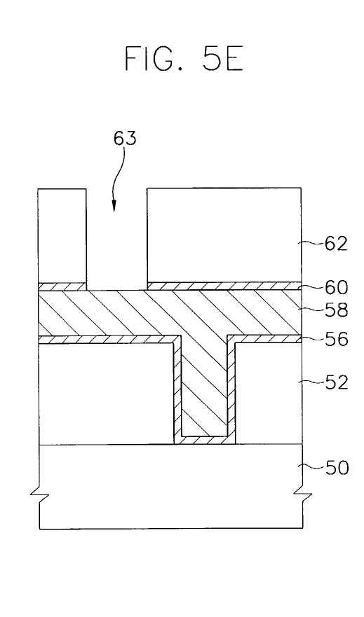

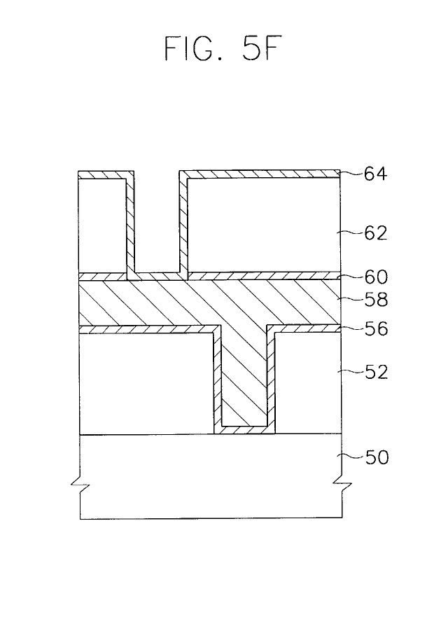

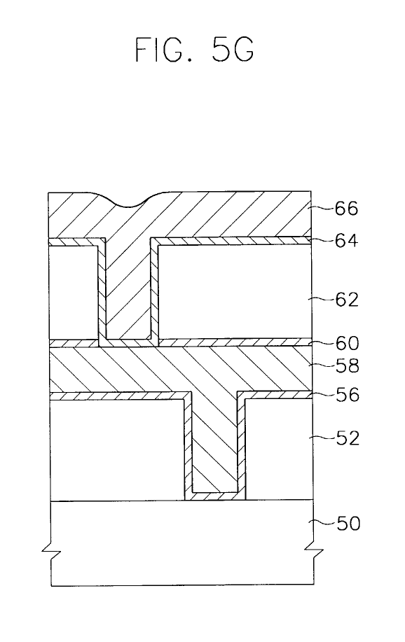

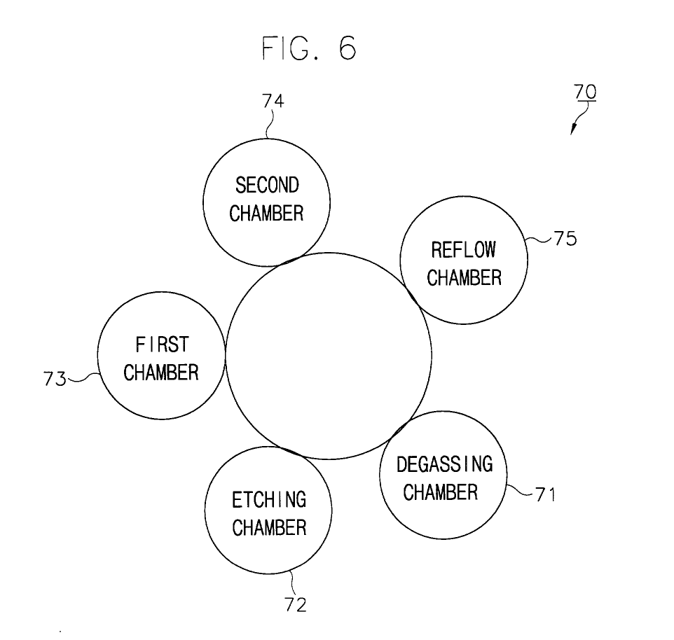

FIGS. 5A to 5G show a method for forming a metal wiring layer including a metal barrier layer deposited by a method for depositing the metal barrier layer.

Referring to FIG. 5A, a first insulation layer 52 having a first opening portion 54 is deposited on the substrate 50 having an underlying structure (not shown) thereon. The first insulation layer 52 comprises an oxide, and the underlying structure includes a MOS transistor having a gate, a source, and a drain. Also, the first opening portion 52 is formed by a photolithography using a photoresist pattern as an etching mask, so that the first opening portion 54 exposes a surface of the substrate in a predetermined region.

Referring to FIG. 5B, a first metal barrier layer 56 is deposited continuously on the first insulation layer 52 and a bottom and a sidewall of the first opening portion 54. The first metal barrier layer 56 is formed by the same method as the above-mentioned method of FIGS. 3A to 3C. The first metal barrier layer 56 comprises a titanium layer and a titanium nitride layer formed on the titanium layer, so that the first metal barrier layer 56 has a good step coverage and a lower electrical resistance.

Referring to FIG. 5C, a first metal layer 58 is deposited on the first metal barrier layer 56 so that the first metal layer fills up the first opening portion 54. The first metal layer 58 is an aluminum layer having a deposition thickness of about 8,000 Å. Then, the first metal layer 58 is reflowed at a temperature of about 500C.° so that the first metal layer more completely fills up the first opening portion 54 with a metal material of the first metal layer 58. The first metal layer 58 without a defect like a void can be formed since the first metal barrier layer 56 has the good step coverage. When the reflow process of the first metal layer 58 is implemented, the first metal barrier layer 56 prevents the metal material comprised of the first metal layer 58 from migrating into the first insulation layer 52 and the partially exposed substrate 50.

Then, a surface of the first metal layer 58 is planarized by performing a planarization process.

Referring to FIG. 5D, an anti-reflective layer 60 that is comprised of titanium is formed on the first metal layer 58 so as to form a photoresist pattern having a high resolution by protecting a diffused reflection generated by a difference between a reflective index of the first metal layer 58 and a reflective index of the photoresist pattern (not shown) that is formed the first metal layer 58.

Referring to FIG. 5E, a second insulation layer 62 having a second opening portion 63 is formed on the anti-reflective layer 60. The second insulation layer 62 is comprised of an oxide. Also, the second opening portion 62 is formed by a photolithography process using a photoresist pattern as an etching mask, so that the second opening portion 63 exposes a surface of the first metal layer 58 of a predetermined region. Here, the second insulation layer 62 and the anti-reflective layer 60 of the predetermined region are sequentially etched by the photolithography process.

FIG. 6 shows an apparatus for depositing the metal barrier layer and the metal layer.

Referring to FIG. 6, the apparatus 70 includes a degassing chamber 71 for purging the substrate 50, an etching chamber 72 for performing a plasma etching, a first chamber 73 for depositing a metal barrier layer, a second chamber 74 for depositing a metal layer, a reflow chamber 75 for performing a reflowing process, and a transferring member (not shown) for transferring a substrate 50 from one chamber to another chamber in the apparatus 70.

The vapor and particles that are generated by the photolithography process for forming the second opening portion 63 adhere to the surface of the second insulation layer 62 and the second opening portion 63. The vapor and the particles are preferably removed because the vapor and the particles can otherwise cause a failure when a subsequent process is performed. Thus, the substrate 50 is placed in the degassing chamber 71 in order to remove the vapor and the particles through the purge.

An oxide layer (not shown) having a thin thickness is formed on the partially exposed first metal layer 58 by the second opening portion 63 because the surface of the partially exposed first metal layer 58 is oxidized during the formation of the second opening portion 63. The oxide layer is removed via the plasma etching by utilizing the plasma chamber 72.

Referring to FIG. 5F, a second metal barrier layer 64 is deposited continuously on the second insulation layer 62 and a bottom and a sidewall of the second opening portion 63 by utilizing the first chamber 73. The second metal barrier layer 64 is deposited by the same method as the above-mentioned method of FIGS. 3A to 3C. Thus, the second metal barrier layer 64 comprises a titanium layer and a titanium nitride layer formed on the titanium layer, so that the second barrier 64 has the good step coverage and the lower electrical resistance.

Referring to FIG. 5G, a second metal layer 66 is deposited on the second metal barrier layer 64 by utilizing the second chamber 74 so that the second metal layer 66 fills up the second opening portion 63. The second metal layer 66 is an aluminum layer having a deposition thickness of about 8,000 Å.

Then, the second metal layer 66 is reflowed at a temperature of no less than about 500C.° by utilizing the reflow chamber 75 to completely fill the second opening portion 63 with the metal of a second metal layer 66. The second metal layer 66 can be deposited without a defect like a void because the second metal barrier layer 64 has a good step coverage. In addition, when the reflow process of the second metal layer 66 is implemented, the second metal barrier layer 64 prevents the metal material comprised of the second metal layer 66 from migrating to the second insulation layer 62 and the partially exposed first metal layer 58 by the second opening portion 63. Further, any thermal stress that may occur during the reflow process may be prevented.

After planarizing the second metal layer 66 by the reflow process, any subsequent process is performed.

The above method for forming the metal barrier layer may be advantageously applied to a method of forming a metal wiring including a multilevel structure. Therefore, a metal wiring having a low resistance and a good step coverage may be easily formed.

In the present invention, when the barrier layer comprising the first and the second metal barrier layers is deposited, the defects may be prevented. Thus, the metal wiring having the barrier layer may have an enhanced reliability. Particularly, since the metal wiring having a multilayered structure has an improved reliability, the present invention may be applied to semiconductor devices having high integration degrees.

Although preferred embodiments of the invention have been described, it will be understood by those skilled in the art that the present invention should not be limited to the described preferred embodiment, but various changes and modifications can be made within the spirit and scope of the invention as defined by the appended claims.

What is claimed is:

1. A method for depositing a metal barrier layer, comprising;
placing a substrate in a sputter chamber such that the substrate is spaced a given distance from a target of a metal material disposed in the sputter chamber;
controlling an amount of a gaseous impurity introduced into the sputter chamber to obtain a pressure within the sputter chamber which is in a pressure transition range, wherein the pressure transition range is defined by a plurality of first pressure values during a increase in the pressure within the sputter chamber and by a plurality of second pressure values during a decrease in the pressure within the sputter chamber which occurs after the increase in the pressure, where the first pressure values are different than the second pressure values at each equal amount of the gaseous impurity being introduced into the sputter chamber; and
allowing accelerated particles to collide with the target to sputter the metal material from the target, wherein a metal barrier layer containing an impurity comprised of the gaseous impurity and the metal material is deposited on the substrate.

2. The method as claimed in claim 1, wherein the given distance is at least 150 mm.

3. The method as claimed in claim 1, wherein the pressure is controlled first by introducing a first amount of the gaseous impurity into the sputter chamber to obtain a higher pressure which exceeds the pressure transition range, and then second by introducing a second amount of the gaseous impurity which is less than the first amount of gaseous impurity into the sputter chamber to obtain a lower pressure than the higher pressure in the sputter chamber.

4. The method as claimed in claim 3, wherein the first amount is introduced for about 2-4 seconds, and the second amount is introduced for about 18-22 seconds.

5. The method as claimed in claim 1, wherein the pressure transition range is from approximately 2 Torr to approximately 4 Torr.

6. The method as claimed in claim 5, wherein the pressure in the pressure transition range is controlled to exceed the pressure transition range.

7. The method as claimed in claim 1, wherein the pressure in the pressure transition range is controlled at a room temperature.

8. The method as claimed in claim 1, wherein the metal material comprises a titanium material, and the impurity comprises nitrogen.

9. The method as claimed in claim 1, wherein a structure having elevated regions and recessed regions is formed on the substrate.

10. The method as claimed in claim 9, wherein the structure includes an opening portion that exposes a surface of the substrate.

11. The method as claimed in claim 9, wherein the structure includes a metal wiring layer, an insulation layer for insulating the metal wiring layer, and an opening portion exposing a surface of the metal wiring layer.

12. A method for deposition a metal barrier layer, comprising;
placing a substrate in a sputter chamber such that the substrate is spaced a given distance from a target of a titanium metal disposed in the sputter chamber;
allowing accelerated particles to collide with the target to sputter the titanium metal from the target, wherein a titanium metal layer is deposited on the substrate;
controlling an amount of a nitrogen gas introduced into the sputter chamber to obtain a pressure within the sputter chamber which is in a pressure transition range, wherein the pressure transition range is defined by a plurality of first pressure values during a increase in the pressure within the sputter chamber and by a plurality of second pressure values during a decrease in the pressure within the sputter chamber which occurs after the increase in the pressure, where the first pressure values are different than the second pressure values at each equal amount of the nitrogen gas being introduced into the sputter chamber; and
allowing accelerated particles to collide with the target to sputter the titanium material from the target, wherein a titanium nitride layer containing the titanium material and nitrogen comprised of the nitrogen gas is deposited on the titanium layer.

13. The method as claimed in claim 12, wherein the given distance is at least 150 mm.

14. The method as claimed in claim 12, wherein the pressure transition range is from approximately 2 Torr to approximately 4 Torr.

15. The method as claimed in claim 12, wherein a deposition thickness of the titanium layer is approximately 250-350 Å, and a deposition thickness of the titanium nitride layer is approximately 250-350 Å.

16. The method as claimed in claim 12, wherein a structure including a metal wiring layer, an insulation layer for insulating the metal wiring layer, and a opening portion exposing a surface of the metal wiring layer is formed on the substrate.

17. The method as claimed in claim 16, wherein the titanium nitride layer deposited in the opening portion has an electrical resistance of approximately 0.55-0.80 ohm per each contact or via.
